(19) United States
(12) Patent Application Publication
(10) Pub. No.: US 2005/0057991 A1
(43) Pub. Date: Mar. 17, 2005

(54) Data rewriting apparatus and data rewriting method

(75) Inventors: Tsugumoto Kosugiyama, Hino-shi (JP); Yosuke Kaneko, Niiza-shi (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: Olympus Corporation, Tokyo (JP)

(21) Appl. No.: 10/925,164

(22) Filed: Aug. 24, 2004

(30) Foreign Application Priority Data
Aug. 29, 2003 (JP) 2003-307541

(51) Int. Cl. G11C 7/00

(52) U.S. Cl. 365/222

(57) ABSTRACT

A data rewriting apparatus which connects with a peripheral device and updates data stored in storage means provided in the peripheral device, includes identifying information storage means for storing identifying information which identifies the peripheral device and the data stored in the storage means in the peripheral device for each of a plurality of peripheral devices of different types, communication means for receiving together update data to update the data stored in the storage means, from a host computer connected with the data rewriting apparatus, update data storage means for storing the update data inputted together by the communication means, and data update means for reading, from the update data storage means, the update data corresponding to the peripheral device connected to the data rewriting apparatus, and updating the data stored in the storage means of the peripheral device.

### CROSS-REFERENCE TO RELATED APPLICATIONS

This application is based upon and claims the benefit of priority from prior Japanese Patent Application No. 2003-307541, filed Aug. 29, 2003, the entire contents of which are incorporated herein by reference.

### BACKGROUND OF THE INVENTION

1. Field of the Invention

This invention relates to a data rewriting apparatus and a data rewriting method, which update data stored in a memory provided in a peripheral device in connection with the peripheral device.

2. Description of the Related Art

In recent years, generally a flash memory being a non-volatile semiconductor memory is included in camera accessories, such as an interchangeable lens and strobe. Firmware programs stored in the camera accessories perform transmission and reception of data with a camera, and perform control such that the camera accessories operate in an optimum manner for the camera.

In the meantime, under economical circumstances in which life cycles of products are shortened and cameras and accessories with new functions are put on the market one after another, indicated is the problem that camera accessories of old models cannot be ready for cameras having new functions.

Therefore, there has been proposed a technique of receiving update data for the firmware program of a camera from a host computer such as an external PC (personal computer), and rewriting the firmware program of a camera accessory by a processing device in the camera (Jpn. Pat. Appln. KOKAI Pub. No. 2000-98467).

However, according to the above technique, if there are a plurality of camera accessories requiring update of their firmware programs, it is necessary to perform an operation of updating the firmware program by connecting the PC and the camera for each of the camera accessories. Therefore, the work for updating the firmware is troublesome and requires much time.

### BRIEF SUMMARY OF THE INVENTION

A data rewriting apparatus according to one aspect of the present invention is a data rewriting apparatus which connects with a peripheral device and updates data stored in storage means provided in the peripheral device, comprising: identifying information storage means for storing identifying information, which identifies the peripheral device and the data stored in the storage means in the peripheral device, for each of a plurality of peripheral devices of different types; communication means for receiving together update data to update the data stored in the storage means, from a host computer connected with the data rewriting apparatus; update data storage means for storing the update data inputted together by the communication means; and data update means for reading, from the update data storage means, the update data corresponding to the peripheral device connected to the data rewriting apparatus, and updating the data stored in the storage means of the peripheral device.

A data rewriting method according to another aspect of the present invention is a data rewriting method of updating data stored in storage means provided in a peripheral device, comprising:
storing identifying information, which identifies the peripheral device and the data stored in the storage means and in the peripheral device, for each of a plurality of peripheral devices of different types; receiving update data to update the data stored in the storage means from a host computer together; storing the update data received together; and reading the update data corresponding to the peripheral device from the stored update data, and updating the data stored in the storage means.

Advantages of the invention will be set forth in the description which follows, and in part will be obvious from the description, or may be learned by practice of the invention. Advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a diagram illustrating a structure of a data rewriting system using a data rewriting apparatus according to a first embodiment of the present invention.

FIG. 2 is a flow chart illustrating a prior processing procedure for update of firmware.

FIG. 3 is a flow chart illustrating a download procedure for update of firmware.

FIG. 4 is a diagram illustrating a structure of accessory history data and firmware data.

FIG. 5 is a flow chart illustrating an operation procedure of data update means in a camera firm-up mode.

FIG. 6 is a flow chart illustrating a procedure of updating firmware of camera accessories.

FIG. 7 is a diagram illustrating signal transmission/reception for updating firmware between camera and camera accessories.

### DETAILED DESCRIPTION OF THE INVENTION

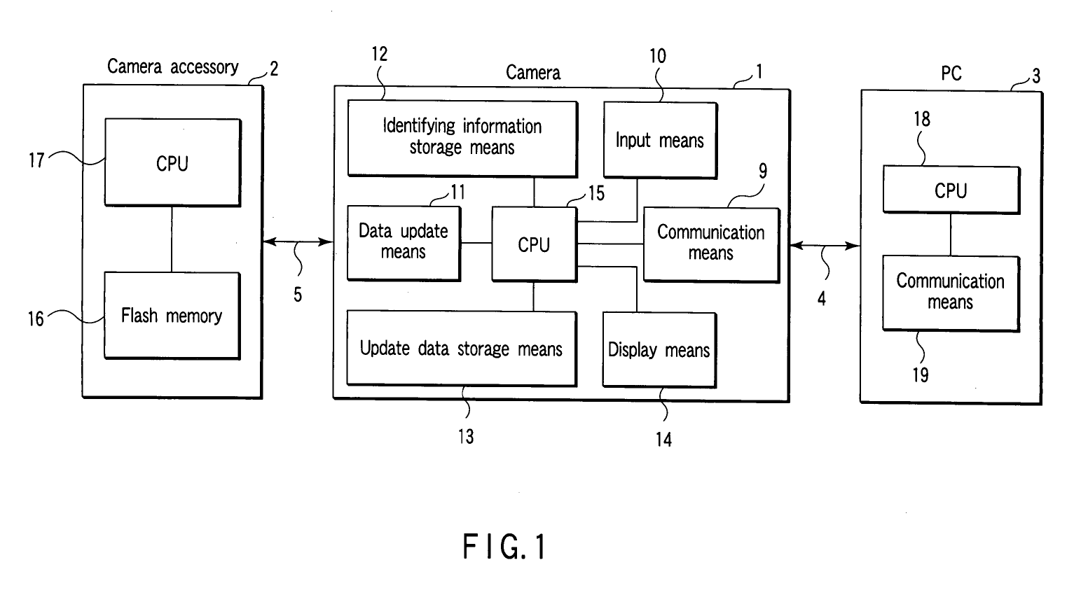

FIG. 1 is a diagram illustrating a structure of a data rewriting system using a data rewriting apparatus according to a first embodiment of the present invention. The data rewriting system comprises a camera 1, a camera accessory 2 and a PC 3, and these component apparatuses are signal-connected by communication lines 4 and 5.

In this embodiment, the camera 1 is a subordinate concept of “data rewriting apparatus”, the camera accessory 2 is a subordinate concept of “peripheral device”, and the PC 3 is a subordinate concept of “host computer”. Further, the communication lines 4 and 5 are paths which are widely used for transmission/reception of information. The communications are not limited to cable communications using conductive lines and optical fibers and the like, but include radio communications using light, acoustic waves and radio waves, etc.

The camera 1 includes communication means 9, input means 10, data update means 11, identifying information storage means 12, update data storage means 13, display means 14 and a CPU 15.

The communication means 9 receives a new firmware program from the PC 3. The input means 10 receives an operation instruction from the user. The data update means 11 identifies the new firmware program, and updates the firmware program of the camera accessory 2. The identifying information storage means 12 is formed of a non-volatile semiconductor memory. The identifying information storage means 12 identifies the camera accessory 2 connected to the camera 1, and stores its identifying information as a history. The update data storage means 13 is formed of a volatile semiconductor memory. The update data storage means 13 stores the new firmware program received from the PC 3. The display means 14 displays the update state of the firmware program (being updated, updated, not updated). The CPU 15 controls operations of the sections of the camera.

The camera accessory 2 includes a flash memory 16 and a CPU 17. The flash memory 16 is formed of a non-volatile semiconductor memory, and stores firmware programs. The CPU 17 controls operations of the sections of the camera accessory.

The PC 3 is provided with a CPU 18 and communication means 19. The CPU 18 controls operations of the sections of the PC 3. The communication means 19 transmits new firmware programs to the camera 1.

Next, operation of the data rewriting system is explained.

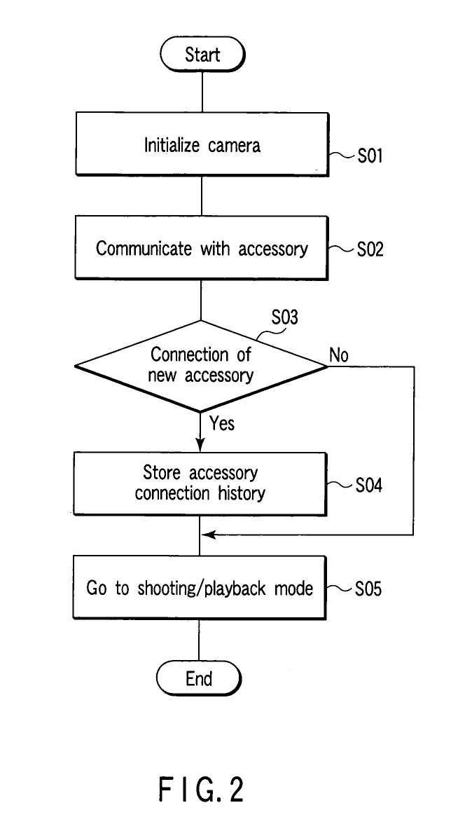

FIG. 2 is a flow chart illustrating a prior processing procedure for update of firmware.

In step S01, the CPU 15 starts when the user turns on the power of the camera 1, and initializes the state of each section of the camera 1. Then, in step S02, the CPU 15 performs communication with the camera accessory 2 connected to the camera 1, and obtains identifying information of the camera accessory 2.

In step S03, the CPU 15 searches the history stored in the identifying information storage means 12 to check whether the camera accessory 2 which is in connection has been connected with the camera before. In the case of No in step S03, that is, if the camera accessory 2 has been connected before, in step S05 the camera 1 goes to a “shooting/playback mode” in which shooting or playback can be performed. In the meantime, in the case of Yes in step S03, that is, if the camera accessory 2 has never been connected before, in step S04 information identifying this new camera accessory 2 is stored in the identifying information storage means 12. Then, after history storage processing, in step S05, the camera goes to the “shooting/playback mode” in which shooting or playback can be performed.

Next, operation of updating firmware is explained.

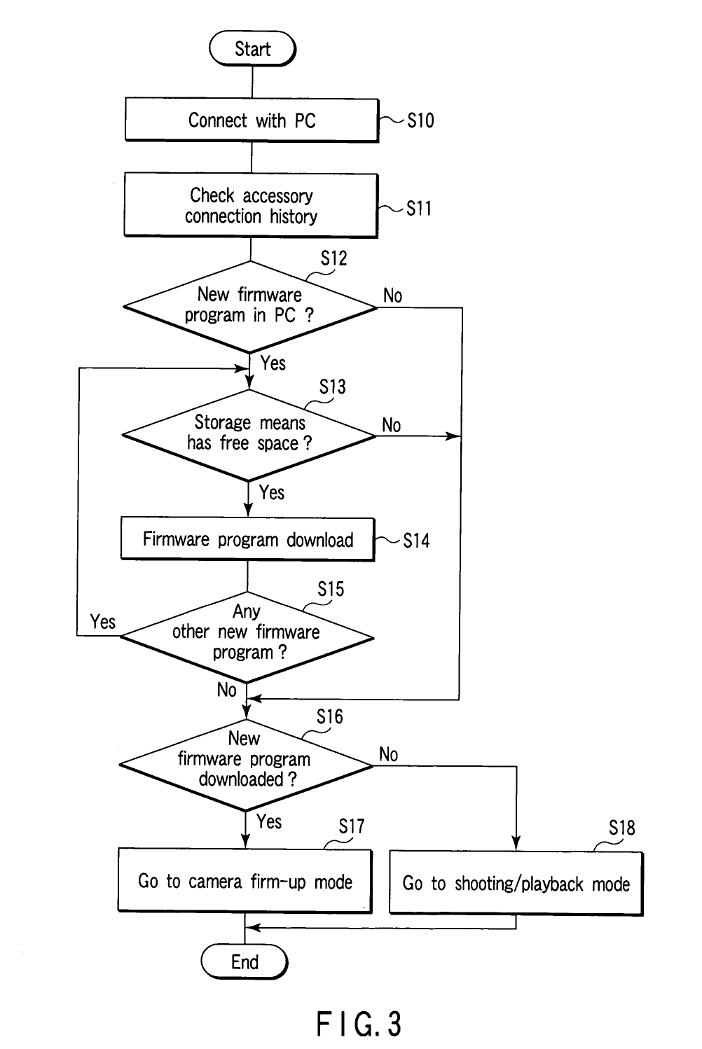

When the user provides an instruction to update the firmware to the camera 1 by the input means 10, the CPU 15 connects with the PC 3 and compares the latest version information of the firmware program in the PC 3 with the connection history of the accessory 2 stored in the identifying information storage means 12, in steps S10 to S12 in FIG. 3. Then, the CPU 15 checks whether a new firmware program is in the PC3.

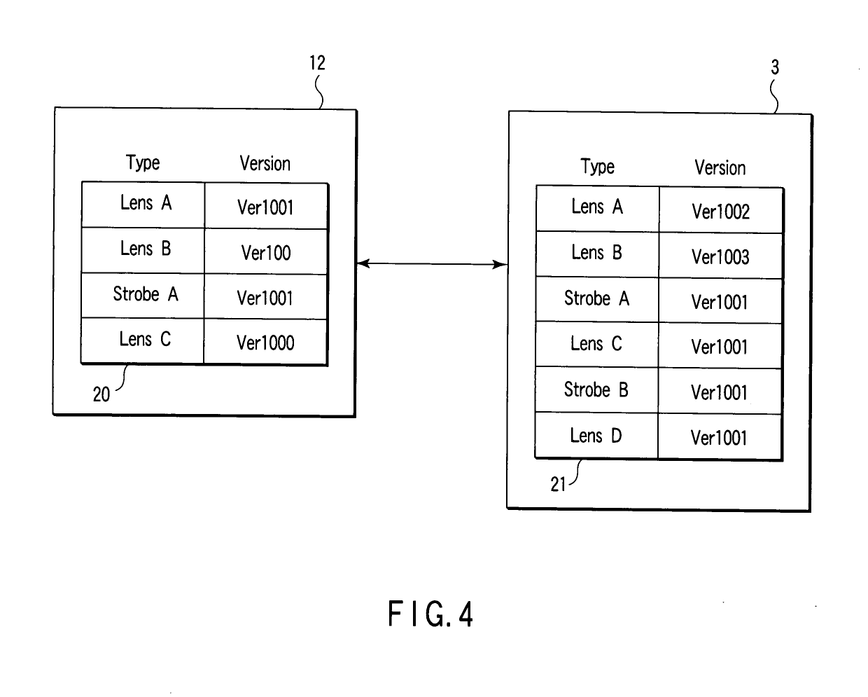

FIG. 4 is a diagram illustrating structures of accessory history data 20 stored in the identifying information storage means 12 and firmware data stored in the PC 3.

The accessory history data 20 includes “type” and “version” serving as identifying information for identifying the camera accessories 2 which have been connected to the camera 1 before as described above. The contents of the identifying information may be of any form, as long as the “type” and “version” of the accessories can be specified therefrom. For example, “Model”, “Model Number”, “Serial Number” or the like may be used, or a special code may be used. However, to achieve the object of the present invention, it is required that the information items “Type” and “Version” identify the firmware program to be updated.

Firmware data 21 includes “Types” of the camera accessories to which the respective latest firmware programs are applied, and the latest “Versions” of the firmware programs, as well as the latest firmware programs. The “Type” and “Version” may be stored as index information, separately from the firmware data.

In FIG. 3 again, in the case of Yes in step S12, that is, if a new firmware program is in the PC3, it is checked in step S13 whether the update data storage means 13 has a required free space. In the case of Yes in step S13, that is, if it has a required free space, the CPU 15 downloads the new firmware program and stores it in the update data storage means 13 in step S14. Then, in the case of Yes in step S15, that is, if there are any other new firmware programs, all the new firmware programs are downloaded in steps S13 to S15, and stored in the update data storage means 13.

Further, in the case of Yes in step S16, that is, if the new firmware program is downloaded, in step S17 the camera goes to “camera firm-up mode” in which the existing firmware program is updated to the new firmware program. In the meantime, in the case of No in step S16, that is, no new firmware program is downloaded, in step S18 the camera goes to the “shooting/playback mode” in which shooting or playback can be performed.

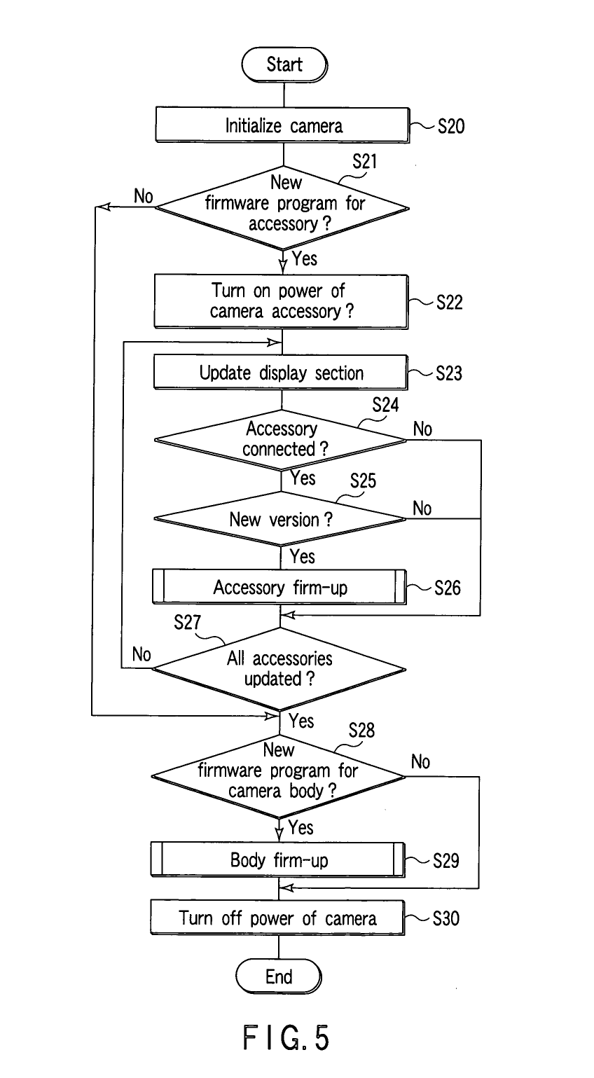

FIG. 5 is a flow chart illustrating an operation procedure of the data update means 11 in the camera firm-up mode.

In steps S20 and S21, after the camera 1 is initialized, the data update means 11 checks whether there are any new firmware programs for camera accessories. In the case of No in step S21, that is, if there are no new firmware programs for camera accessories, the operation goes to step S28 explained below.

In the case of Yes in step S21, that is, if there is a new firmware program for a camera accessory, the power to be supplied to the camera accessory 2 is turned on. Then, in step S23, the camera 1 displays an instruction for promoting user's operation on the display means 14, for example, “please connect lens A”.

In the case of No in step S24, that is, if the desired camera accessory 2 is not connected after a predetermined time has passed, in steps S27 and S23, update of the firmware program is canceled, and an instruction to update the next firmware program is started.

In the case of Yes in step S24, that is, if a camera accessory 2 is connected, it is checked in step S25 whether there is a new version of the firmware program corresponding to the connected camera accessory 2. In the case of No in step S25, that is, if there is no new version of the firmware program of the connected camera accessory 2, the camera 1 judges that a wrong camera accessory 2 is connected, and cancels firmware update operation and starts an instruction to update a firmware program which has not yet been updated. In the case of Yes in step S25, that is, if there is the new version of the firmware program corresponding to the connected camera accessory 2, update of the firmware program is started in step S26.

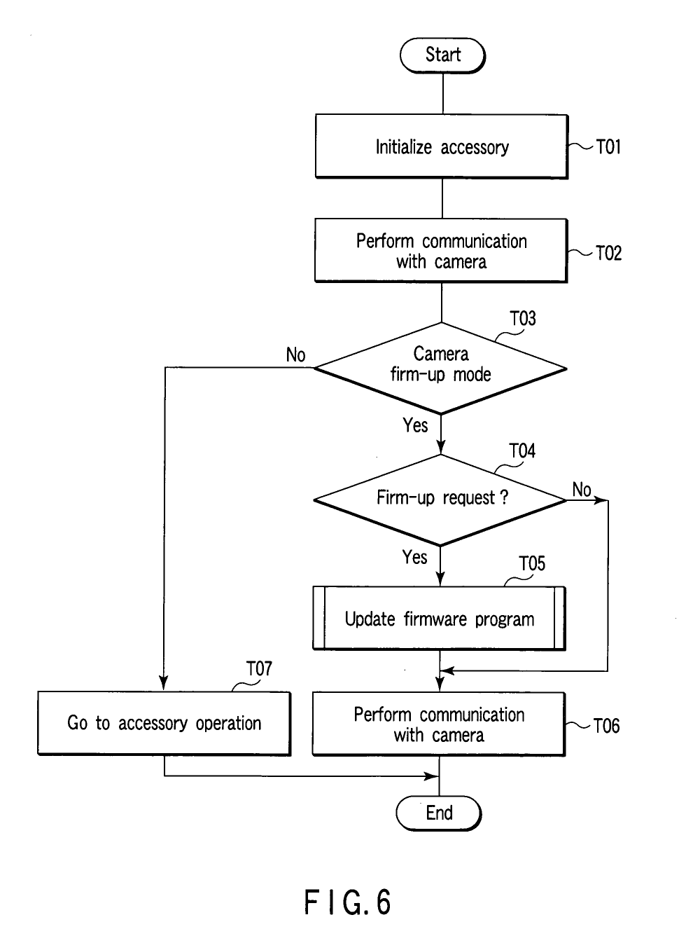

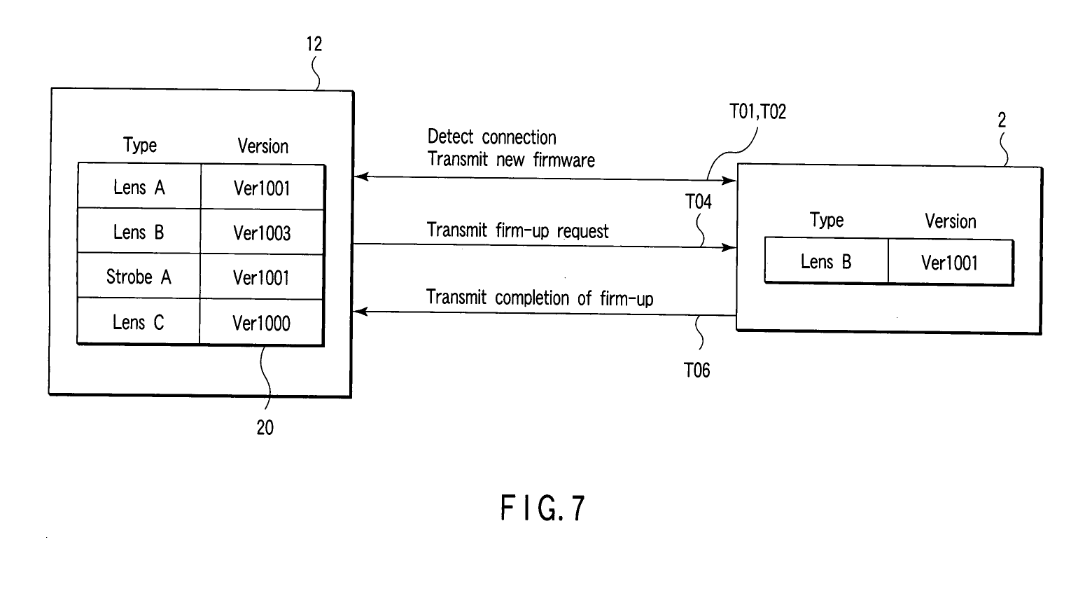

FIG. 6 is a flow chart illustrating a firmware update procedure for the camera accessory 2, and FIG. 7 is a diagram illustrating transmission/reception of signals for updating the firmware program, which are performed between the camera 1 and the camera accessory 2. The update operation of the firmware program is explained with reference to FIGS. 6 and 7.

In steps T01 and T02 in FIG. 6, the CPU 17 of the camera accessory 2 is started when the power is supplied from the camera 1. Then, the CPU 17 initializes the camera accessory 2, and performs communication with the camera 1. Specifically, the CPU 17 transmits information of the version of the current firmware program, and receives a firmware program from the camera 1.

In the case of Yes in step T03, that is, if the camera 1 is in the firm-up mode, and in the case of Yes in step T04, that is, if a firm-up request is transmitted from the camera 1, the CPU 17 updates the firmware program in step T05. Then, after the firmware program has been updated, in step T06, the CPU 17 notifies the camera 1 of completion of update of the firmware program.

In the meantime, in the case of No in step T04, that is, if the camera 1 does not transmit a firm-up request within a predetermined time, in step T06, the CPU 17 notifies the camera 1 of cancellation of firmware update. Further, in the case of No in step T03, that is, if the camera 1 is not in the firm-up mode, in step T07, the accessory 2 goes to normal accessory operation.

In FIG. 5 again, when the data update means 11 of the camera 1 receives notification of completion of firmware update, in step S27 the data update means 11 checks whether versions of firmware programs of all the predetermined camera accessories 2 have been updated.

Then, in the case of Yes in step S27, that is, if versions of firmware programs of all the camera accessories 2 have been updated, the data update means 11 starts operation for updating the version of the firmware program of the camera 1.

Specifically, in step S28, the data update means 11 checks whether a new firmware program for camera body is stored in the update data storage means 13. In the case of Yes in step S28, that is, if it is stored, the data update means 11 updates the camera body firmware program in step S29.

Thereafter, when update of the camera body firmware program is completed, or in the case of No in step S28, that is, if no new firmware program for camera body is stored in the update data storage means 13, the power of the camera 1 is turned off, and the firmware update operation is ended. Further, the system may be configured such that the firmware program stored in the update data storage means 13 is deleted when update of the firmware program is verified.

As described above, according to this embodiment, identifying information for identifying peripheral devices for camera such as a shooting lens and a strobe, which have been used or may be used, is transmitted to the host computer, and the host computer transmits all update programs for the peripheral devices, such as lens which have been used, to the camera body together. This simplifies rewriting of firmware programs of a plurality of peripheral devices such as shooting lens, as described above.

In the above embodiment, firmware programs of the camera accessories 2 which have been connected to the camera 1 before are updated. However, the present invention is not limited to it, but firmware programs may be updated for camera accessories 2 which may be connected to the camera 1 hereafter. For example, information of camera accessories 2 which can be connected to the camera 1 is extracted from the PC 3, and the camera accessories 2 may be the objects of update.

Further, the latest firmware programs stored in the PC 3 may be downloaded by the PC 3 from a server, or the camera 1 may directly connect a server to obtain the latest firmware programs;

Furthermore, although the firmware is updated in the above embodiment, the present invention is not limited to it, but data, which is a superordinate concept of “firmware”, may be updated.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A data rewriting apparatus which connects with a peripheral device and updates data stored in storage means provided in the peripheral device, comprising:
identifying information storage means for storing identifying information, which identifies the peripheral device and the data stored in the storage means in the peripheral device, for each of a plurality of peripheral devices of different types;
communication means for receiving together update data to update the data stored in the storage means, from a host computer connected with the data rewriting apparatus;
update data storage means for storing the update data inputted together by the communication means; and
data update means for reading, from the update data storage means, the update data corresponding to the peripheral device connected to the data rewriting apparatus, and updating the data stored in the storage means of the peripheral device.

2. A data rewriting apparatus according to claim 1, wherein the identifying information stored in the identifying information storage means includes information which identifies a type of a peripheral device which has been connected to the data rewriting apparatus before.

3. A data rewriting apparatus according to claim 2, wherein the storage means is a non-volatile semiconductor memory.

4. A data rewriting apparatus according to claim 2, wherein the data stored in the storage means is firmware of the peripheral device.

5. A data rewriting apparatus according to claim 1, wherein the identifying information stored in the identifying information storage means includes information relating to a version of the data stored in the storage means.

6. A data rewriting apparatus according to claim 5, wherein the communication means receives latest update data from the host computer, with reference to the information relating to the version of the data stored in the storage means.

7. A data rewriting apparatus according to claim 6, wherein the storage means is a non-volatile semiconductor memory.

8. A data rewriting apparatus according to claim 6, wherein the data stored in the storage means is firmware of the peripheral device.

9. A data rewriting apparatus according to claim 5, wherein the storage means is a non-volatile semiconductor memory.

10. A data rewriting apparatus according to claim 5, wherein the data stored in the storage means is firmware of the peripheral device.

11. A data rewriting apparatus according to claim 1, wherein the data stored in the identifying information storage means is identifying information of a peripheral device which is connectable to the data rewriting apparatus.

12. A data rewriting apparatus according to claim 11, wherein the storage means is a non-volatile semiconductor memory.

13. A data rewriting apparatus according to claim 11, wherein the data stored in the storage means is firmware of the peripheral device.

14. A data rewriting apparatus according to claim 1, further comprising display means for displaying that the data stored in the update data storage means has been updated, has not yet updated, or is being updated.

15. A data rewriting apparatus according to claim 14, wherein the storage means is a non-volatile semiconductor memory.

16. A data rewriting apparatus according to claim 14, wherein the data stored in the storage means is firmware of the peripheral device.

17. A data rewriting apparatus according to claim 1, wherein the storage means is a non-volatile semiconductor memory.

18. A data rewriting apparatus according to claim 1, wherein the data stored in the storage means is firmware of the peripheral device.

19. A data rewriting method of updating data stored in storage means provided in a peripheral device, comprising:
storing identifying information, which identifies the peripheral device and the data stored in the storage means and in the peripheral device, for each of a plurality of peripheral devices of different types;
receiving update data to update the data stored in the storage means from a host computer together;
storing the update data received together; and
reading the update data corresponding to the peripheral device from the stored update data, and updating the data stored in the storage means.
